(19) United States
(12) Patent Application Publication
(10) Pub. No.: US 2009/0064498 A1
(43) Pub. Date: Mar. 12, 2009

(54) Membrane spring fabrication process

(75) Inventors: Sammy Mok, Cupertino, CA (US); Frank J. Swiatowiec, San Jose, CA (US)

Correspondence Address: PATENT LAW OFFICES OF DAVID MILLERS, 1221 Sun Ridge Road, Placerville, CA, 95667, US

(73) Assignee: InnoConnex, Inc.

(21) Appl. No.: 12/288,169

(22) Filed: Oct. 16, 2008

Related U.S. Application Data
(63) Continuation-in-part of application No. 11/900,795, filed on Sep. 12, 2007.
(60) Provisional application No. 60/980,411, filed on Oct. 16, 2007.

(51) Int. Cl. G01R 3/00

(52) U.S. Cl. 29/874

(57) ABSTRACT

Processes are described for building low compliance MEMS type C-spring probes in a coupon form that can be used as replaceable probes in probe card applications. The coupons have plated spring structures and a plated frame that holds a thin polyimide film in tension. The film keeps the probes and their tips of the top probes aligned to the pads of an IC being tested and the probes and tips of bottom probes aligned to the pads of a probe card high density interconnect that routes to an IC tester.

### CROSS-REFERENCE TO RELATED APPLICATIONS

This patent document is a continuation-in-part and claims benefit of the earlier filing date of U.S. patent application Ser. No. 11/900,795, filed Sep. 12, 2007, which is hereby incorporated by reference in its entirety. This patent document also claims benefit of the earlier filing date of U.S. provisional Pat. App. No. 60/980,411, filed Oct. 16, 2007, which is hereby incorporated by reference in its entirety.

### BACKGROUND

Electrical testing of unpackaged integrated circuits (ICs) is performed on ICs using probe cards. Probe cards provide the electrical path between a test system and the pads on ICs while they are in wafer form. Fabrication of micro springs as probes on advanced probe cards traditionally involves processing of complex 3D structures requiring many repeated steps such as the one used by Microfabrica of Van Nuys California, or several complex plating process followed by an assembly process such as the one used by FormFactor of Livermore Calif. In addition, these springs have to be fabricated onto or firmly mounted onto a hard interconnect substrate that acts as a solid platform to withstand the bending moment of the probes. Simple processes able to fabricate springs on flexible membranes which minimize spring fabrication costs, assembly costs and to simplify repair of defective springs in the field are desired.

### BRIEF DESCRIPTION OF THE DRAWINGS

FIGS. 1A and 1B respectively show a perspective view and cross-sectional view of a coupon approach for field replaceable MEMS springs.

FIG. 1C shows replaceable coupons mounted on an HDI.

FIG. 2 is a flow diagram of a process used in one embodiment of the present invention based on processing on a membrane supported by a ring.

FIGS. 3A, 3B, 3C, 3D, 3E, 3F, 3G, 3H, 3I, 3J, 3K, 3L, 3M and 3N show cross-sectional views of structures formed during an embodiment for the process flow of FIG. 2.

FIG. 4 is a flow diagram of a sequence of process steps used in one embodiment of the present invention based on processing on a wafer and then transferring to a support ring.

FIGS. 5A, 5B, 5C, 5D, 5E, 5F, 5G, 5H, 5I, 5J, 5K, 5L, 5M, 5N, 5O, 5P, 5Q, 5R, and 5S show cross-sectional views of structures formed during of an embodiment for the process flow of FIG. 4.

Use of the same reference symbols in different figures indicates similar or identical items.

### DETAILED DESCRIPTION

In accordance with an aspect of the invention, simple processes can yield springs suspended on a membrane that is suitable for IC wafer probe applications as well as other connector applications requiring high signal density, low profile and high frequency. These springs can be formed in a C shape that exerts minimal bending moment on the attached membrane and can be organized as small coupons enabling them to be easily replaced. The processes for fabricating theses springs described herein provide alternative ways of building the coupon structures described in U.S. patent application Ser. No. 11/900,795, entitled “COMPLIANCE PARTITIONING IN TESTING OF INTEGRATED CIRCUITS,” filed on Sep. 12, 2007. These low compliance coupons of springs can be used as part of a flexible compliance partitioning architecture as described in U.S. patent application Ser. No. 11/900,795 or in a more rigid architecture that uses very flat (<15 microns) polished surfaces as a reference. Using a flat and polished High Density Interconnect (HDI) substrate like Pyrex that tracks the coefficient of thermal expansion of silicon both minimizes the X-Y alignment and Z direction movement also enables utilization of these lower compliance coupons in probing of silicon or other semiconductor devices.

An objective for this embodiment is to create a simpler low compliance and thus shorter probe that is easily repaired in the field for integrated circuit testing and can also be tiled to create large area probe cards economically. To fabricate a probe that can make a reliable electrical contact, the probe must push or scrub away the oxides that form on aluminum or other conductive pads while maintaining a minimum contact force of greater than 1 gram. Some higher current applications require even higher force to ensure low contact resistance so as to prevent the electrical contact from over heating and causing the contact resistance to increase. The probe must apply these forces and have sufficient scrub or overdrive to ensure that the probe tip creates an electrically clean surface. The probe design must also compensate for the compliance needed to make up for the non-planarity in the probe card. For reaching the required force, higher compliance means the spring lever arm sees more stress and the stress must stay below the fracture point of the probe material or the spring constant of the probe will weaken and/or the spring will crack. To attain higher compliance requires either increasing the yield strength of the material or making the probe lever arm larger. Most MEMS probes are fabricated using a nickel based spring material like nickel cobalt. Using higher yield strength materials makes the probes significantly more difficult to fabricate. The scaling of IC pads to smaller sizes makes it impractical to make the probes larger in cross sectional area or length. A C-shaped spring probe has two lever arms that are balanced against each other which would reduce the maximum fracture stress seen in the spring material as well as minimizing the force that is normally needed to anchor the probes to rigid substrates or tiles. The two lever arm counter balancing design effectively distributes the material fracture stress over the combined length of the two lever arms. The counter balancing design also contributes to shorter probes. The probe structure also enables freestanding probes that are held in place by a thin membrane to form a coupon of probes that can be temporarily tacked in place on an HDI. The coupons simplify the repair process and allow repairs to be done at a customer's manufacturing site.

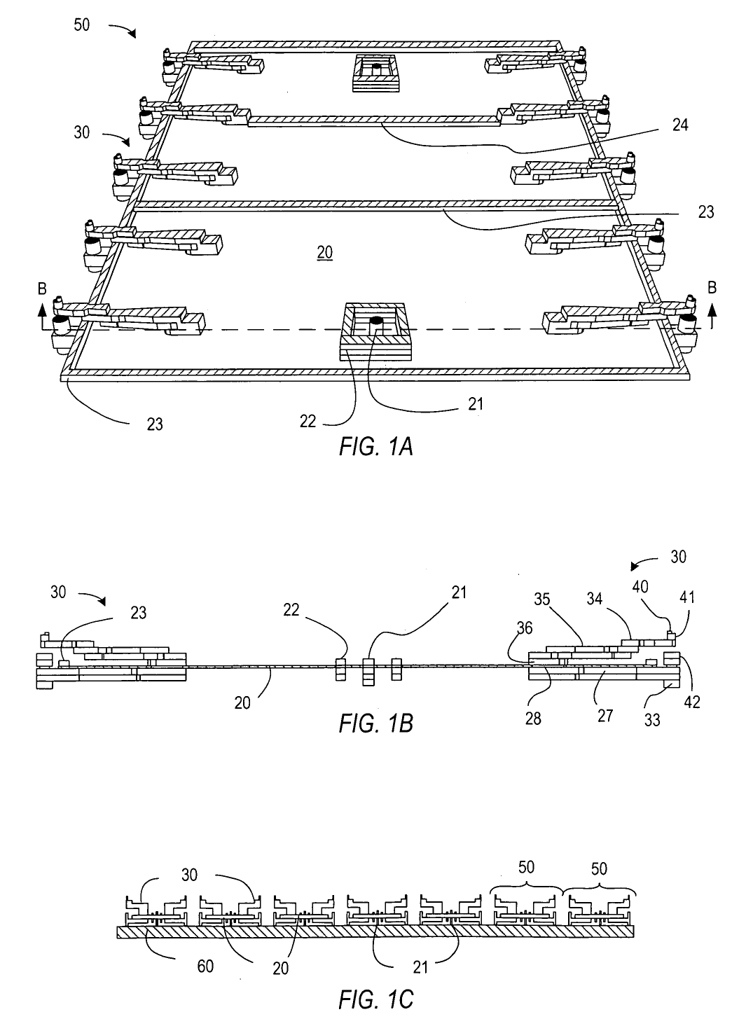

For DRAM memory probing applications, large array solutions (>1000 die sites being tested in parallel) commonly need MEMS springs to contact and escape from 40 to 150 electrical pads in each memory die site on the wafer. Most of the MEMS probes in these highly parallel probing arrays cannot be repaired at the customer's site. FIGS. 1A and 1B respectively show a perspective and a cross-sectional view of a coupon 50 of floating probes covering either one die site or several die sites, e.g., several memory chips that are still part of a wafer. FIG. 1C shows multiple coupons 50 attached to a HDI 60.

In coupon 50 of FIGS. 1A and 1B, springs 30 are suspended by a flexible and insulating membrane 20 typically made of polyimide. Membrane 20 is preferably placed in the middle layers of the springs 30 as shown in FIG. 1B. Membrane 20 is kept in tension by a coupon frame 23 typically made from the same material (e.g., a nickel material) as springs 30 and fabricated as part of the spring building process through features in the lithography. Membrane 20 holds all springs 30 and attachment points 28 in the proper positions (e.g., in a pattern matching die pads) relative to each other in coupon 50.

The bottom spring arm 27 of each spring 30 has a single tip 33 that interfaces to a gold or other noble metal pad on the HDI substrate. This tip 33 can be made of rhodium (Rh), Palladium Cobalt (PdCo) alloys or hard gold. The top spring arm of each spring 30 includes cantilevered sections 34 and 35 and has a shaped noble metal tip 40 of a material such as rhodium (Rh) or a Palladium Cobalt (PdCo) alloy which makes electrical contact to the IC pad under test. Tip 40 is attached to a post 41 which give tip 40 enough height to clear insulation layers around the IC pads to be contacted. Spring probes 30 are designed to simultaneously apply force to the cantilever arm sections 34 and 35 and lower arm 27, which opposes arm sections 34 and 35 to counter balance their individual probing forces. This configuration eliminates the requirement for a strong rigid substrate with a solid spring anchor that is required by traditional MEMS probes. Without a solid anchor, traditional probes could break away from the substrate during testing. However, each spring 30 applies minimal torque on membrane 20 and the supporting substrate interface at point 28. This enables the probes to vertically float and to dynamically compensate for any local flexing in the probe card. Membrane 20 and frame 23 maintain the relative x-y location of the probe tips 30. A stand-off 42 can be provided to limit the overdrive of lever arm consisting of 34 and 35 and 36 provides probe height for the lever arm.

Unlike existing probe cards where individual MEMS springs are electrically and mechanically attached to a HDI or tile, the electrical contact pads on the HDI for the coupon interface do not require or have solder or conductive adhesives which need to be cleaned off before replacing probes as part of a repair process. The coupons 50 of FIG. 1A can be tacked or pressure fit into place via the attachment points 21. The force from the DUT contact tip 40 will be transferred to the HDI contact tip 33 which will provide a reliable electrical contact to the gold pads on the HDI substrate. This means a damaged coupon can be removed and a new spare coupon replaced by customers at their test facilities without damaging electrical pads on the HDI substrate. This provides a MEMS-based repairable solution for large area memory testing.

There are multiple ways to structure the attachment points 21 on the coupon membrane 20, which will typically be fabricated with the same nickel as the springs and coupon frame 23. FIGS. 1A and 1B show a stud 21 inside of a small frame 22. This stud can be tacked to an alignment pad on the HDI substrate 60 in FIG. 1C using adhesive, solder or brazed into position after the coupon has been aligned. For removal, a heat source such as laser can be used to heat up the stud and to soften the solder or can be used to cut the attachment point to release the coupon from the HDI substrate. Unused, extra, attachment points can be placed on the coupon and on the HDI substrate to bond to fresh surfaces if needed when attaching new coupons. Alternately, the stud can be made longer and press fit into retaining holes in the HDI substrate. Another alternative for attachment is to build a post on the HDI substrate and create a nickel frame that can be a press fit or clipped over the HDI post with a cap. For this alternative, any damaged probes on a die site would have the clipped portion of the frame cut away from the post using a laser. The coupon could then be removed without damaging the post and a new coupon pressed in place using the original HDI post.

FIG. 1C is an example of how coupons 50 could be attached to HDI substrate 60. It is important to note that springs 30 can extend pass the edge of the coupon 50 on which the spring 30 is attached. This eliminates the need to create a butt joint between tiles which creates inaccuracy in spring tip placements. The freedom to design a coupon 50 that allows each spring 30 to extend beyond the base area of the coupon 50 also simplifies repair of damaged coupons.

The replaceable die site coupon described above has several advantages over the solder method of attaching MEMS springs. The equipment needed to align and solder over a 300 mm wide area is expensive to build. The coupons are designed so that the tolerances needed to align the die sites are less critical to align from a mechanical placement point of view. The alignment is set by the photolithographic processes that are used in building the HDI and the coupon. A very precise large area die site placement tool is not required for probe head assembly. The coupon design can be made such that some electrical routing 24 can be performed in the coupon 50 and capacitors can be added for decoupling. The coupon configuration can be applied to other IC applications such as the burn-in and testing of individual ICs, which can then be mounted in a multi-die package. It can also act as a socket for stacking ICs. Coupons can also be used as interposers or springs between the probe card HDI and the PCB. Traces on the coupon can connect one set of springs to another set of springs. This can be applied to connecting pads on one pitch to pads on another pitch to provide a fan-out function.

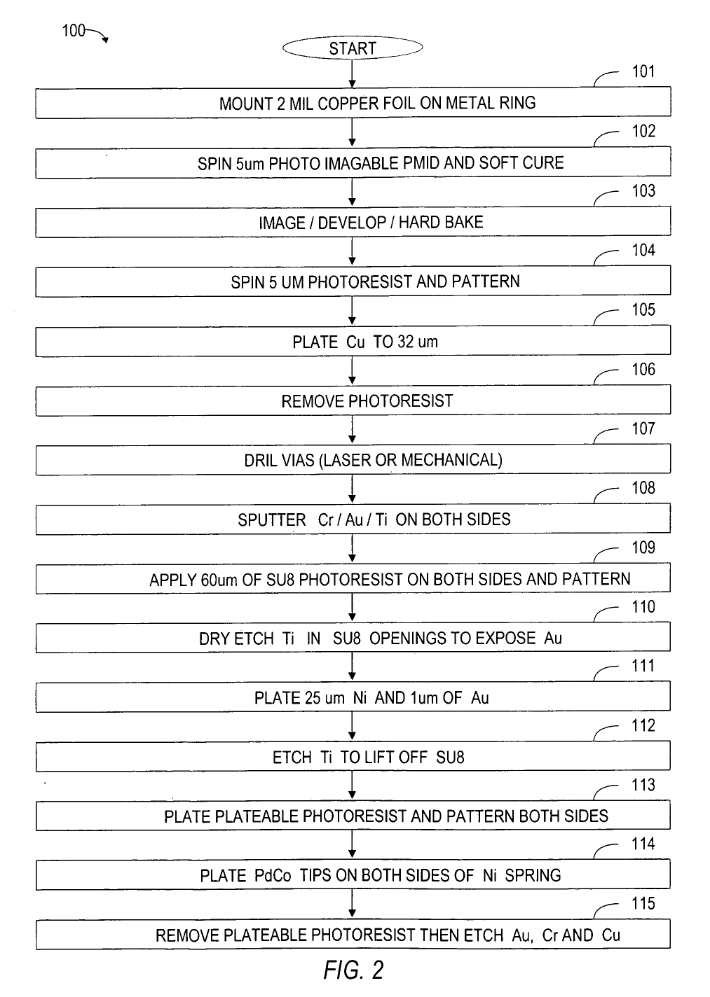

FIG. 2 shows a series of process steps that is one embodiment of a process flow 100 used to fabricate springs on a membrane. Typically these steps will be performed on a membrane that would be in the shape of a round wafer to utilize existing semiconductor processing equipment and to simplify the spin coating of polyimide and photo resists. This is a simpler process flow than the one described in the patent referenced above, in which the process is based on a plate and mechanical lap process, as used by Microfabrica of Van Nuys Calif. The process of FIG. 2 is suitable for springs with compliance of 50 μm but can be extended to compliance of greater than 100 μm by increasing the thickness of the individual layers and changing the shape, such as extending the length of the spring or shape of the arm. This process does not require a strong mechanical attachment at the electrical interfaces and utilizes fewer process steps to fabricate the springs. Therefore, process 100 is much more economical to perform. An important feature of this embodiment of the invention is the use of a thin copper film with a coating of polyimide as a sacrificial starting substrate where nickel springs are formed on both sides of this film. After this copper film has been etched away, the nickel springs can then be compressed against each other utilizing the space vacated by the copper film. The initial thickness of the copper film is the compression range of the spring pair. The polyimide serves to hold the springs in position relative to each other, forming a stand-alone coupon of springs.

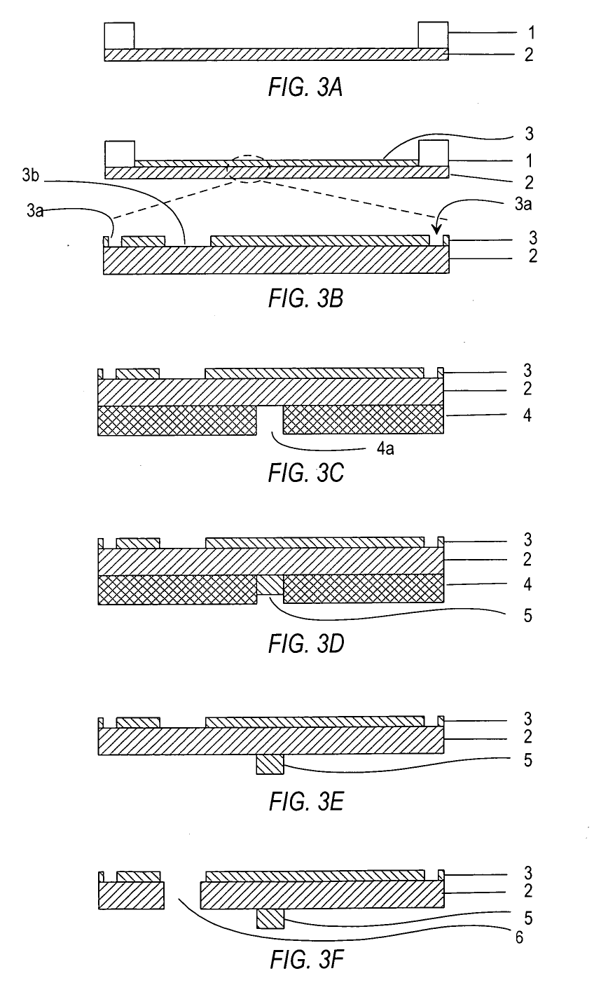

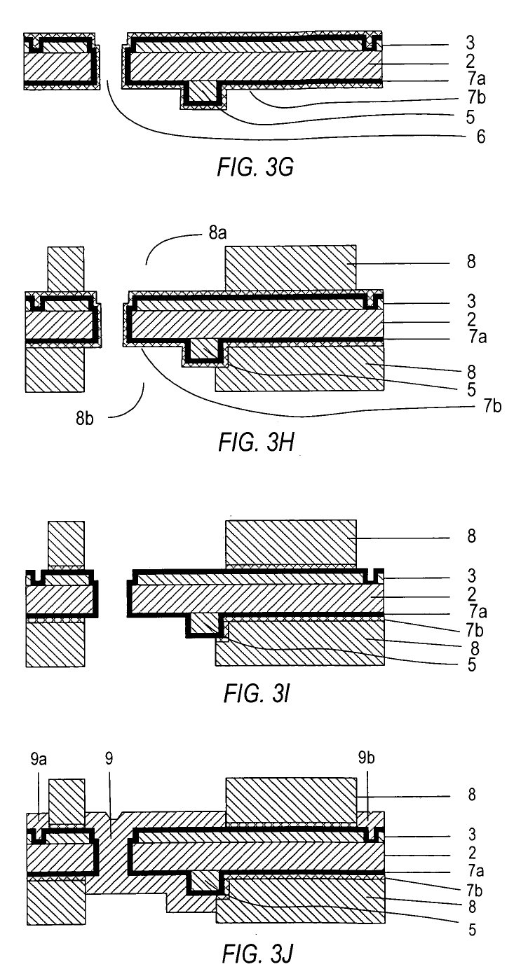

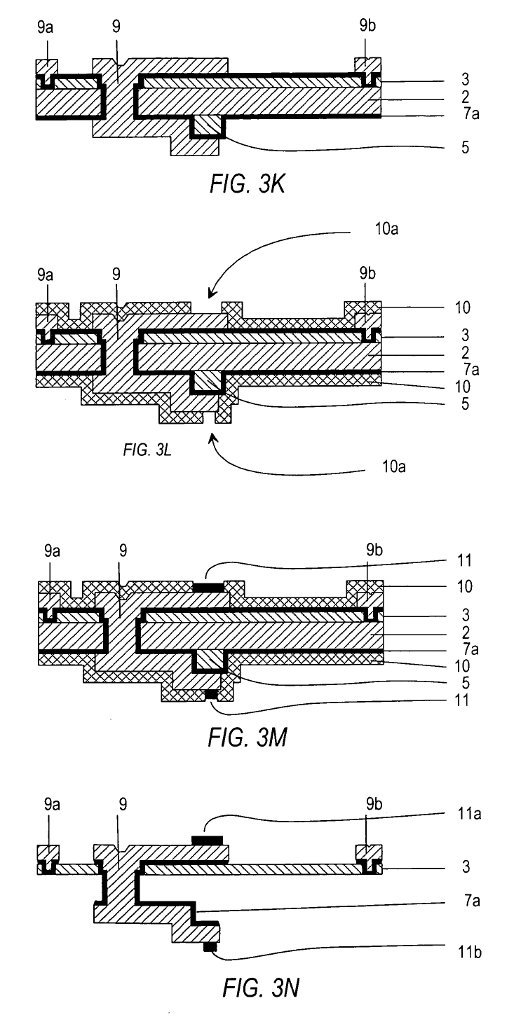

The structures built by following the process flow of FIG. 2 are shown in FIGS. 3A to 3N. There are multiple ways to fabricate the starting copper and polyimide film. Steps 101 to 103 of FIG. 3 shows a way where a copper film 2 of the thickness, 35 microns to 100 microns for this embodiment, is mounted taunt on a metal support ring 1 as shown in FIG. 3A. The target thickness for this example is 50 microns. The thickness of this film 2 will define the compliance range of the resulting C-Springs. A Polyimide layer (PMID) 3 with approximately 5 microns thickness is spun onto the copper and soft cured in step 102. Ideally a photo-imageable polyimide can be used to coat and pattern photographically to define positions of vias 3a. Step 103 is the exposure (imaging), development and hard backing step that results in the creation of vias 3a, which will be used to anchor a future frame and via 3b which will be part of a structure to connect the top and bottom sections of a C shaped spring. The use of photo-imageable polyimide eliminates the need to spin photoresist to pattern the vias 3a. However, for some applications the materials properties of non-imageable polyimide may be preferred because the material may be more stable at higher temperatures even though non-imageable polyimide requires an additional photoresist spinning process step to define the vias 3a and 3b.

Alternately, the structure of FIGS. 3A and 3B can be fabricated using a hard substrate such as glass, ceramic or silicon wafer. A layer of titanium and copper is sputtered or evaporated onto this substrate. The titanium layer would preferably be 2000-5000 A thick and serves as the release layer. The copper layer can be 500-2000 μm thick and acts as a plating seed. Copper is then plated onto this film to the desired thickness, 50 to 75 μm in this case. Photo-imageable polyimide film 3 is then coated onto the plated copper layer and patterned. The support ring 1 is then glued onto the perimeter of the wafer over the polyimide surface film 3. An adhesive such as B-state epoxy would be preferred for the attachment. The hard substrate is then removed by etching the titanium release layer. This method is more expensive, but provides a more uniform film than can be obtained with using copper film as the starting material, which was described as the process of FIG. 2.

In step 104 of FIG. 2, a thick photoresist layer 4, as shown in FIG. 3C, is coated onto the second surface (bottom) 2 of the membrane that does not have the polyimide. The thickness of this resist layer 4 needs to be high enough for the raised tip of the spring to clear the base of the spring during compression. For this embodiment 35 μm would be preferred for a 50-μm thick starting copper film. Openings 4a in this resist layer 4 are patterned in places where the tips of springs will be located on the lower part of the C spring structure.

In step 105, copper 5 is plated in the openings 4a of the photoresist layer 4 as shown in FIG. 3D. The starting copper film 2 serves as the plating seed for plated copper 5. This plated copper 5 serves as a post to elevate a nickel structure that will support the bottom spring tip.

In step 106, the photoresist 4 of step 104 is removed leaving the plated copper posts 5 on the copper film 2 as shown in FIG. 3E.

In step 107, holes 6 are drilled in the copper film 2 in positions where the base of the springs will be created as shown in FIG. 3F. These holes 6 should align to the openings 3b in the polyimide layer 3. Each spring will have one or more of these vias to connect the top spring element of a C shaped spring to the bottom spring element. To protect the patterned features 3a already on the copper film 2 from debris or damage, it is preferred to coat both surfaces of the copper film wafer with photoresist that is soft cured before drilling. The size of the holes 6 will be a function of the size of the springs, but will typically be in the 40 microns to 100 microns range to match with spring pitches of 80 microns to 120 microns. If protective photoresist was used, it is then removed after drilling process. The drilling can be done with mechanical drilling or laser drilling. If needed, a quick dip etch of copper may be used to remove any stray slivers of copper.

In step 108, both sides of the structure are coated with sputtered Cr/Au film 7a and a Ti film 7b shown in FIG. 3G. The thickness of Cr in layer 7a could be in the 200 A-500 A range serving as an adhesion layer to the polyimide. The thickness of Au in layer 7a could be 500 A to 2000 A and serves as the seed layer. Ti film 7b could be 1000 A to 3000 A and serves as the release layer for the thick photoresist 8 as shown in FIG. 3H. SU8 or an alternative thick photoresist that is easier to remove at later steps in the process could be used.

In step 109, a thick photoresist 8 described above is applied on both sides of the coupon. A thickness of 60 μm is preferred to match the dimensions described above for this embodiment. This resist 8 is patterned to form openings 8a and 8B as shown in FIG. 3H and serves as the plating barriers for the creation of nickel springs.

In step 110, the openings 8a and 8b in the resist of step 109 are etched, preferably by dry etch, to remove the Ti in the plating windows exposing the Au for plating. This resulting structure is shown in FIG. 3I.

In step 111, nickel 9 is electro-plated into hole 6 of FIG. 3F that was created in step 107 and in openings 8a and 8b of FIG. 3H, which were created as part of resist step 108. The nickel is plated on both sides of the membrane creating spring structure 9 as shown in FIG. 3J. A thickness of about 25 μm is possible for the forgoing set of dimensions described for this embodiment. A layer of gold about 1 micron or thinner can also be plated over the nickel to act as a seed layer to simplify a follow on plateable photoresist step. The nickel thickness is a function of the spring design which is governed by the desired spring force, compression distance and dimensions of the spring. This plating in the drilled holes 6 connects the springs on both sides of the copper and polyimide film. This creates a nickel C shaped spring structure 9 shown in FIG. 3J with a continuous plated film which is less sensitive to delaminating between films than spring fabricated as separate plated structures. A plated structure 9a in FIG. 3J creates a stud for mechanical attachment to the HDI. A plated structure 9b in FIG. 3J will become the frame 23 shown in FIG. 1a that supports the polyimide film 20 of the coupon. In FIG. 3J, this polyimide film is labeled 3.

In step 112, the plating mask 8 of step 109 is removed to leave the structure of FIG. 3K. For hard to remove resists like SU8 which cannot be etched, the Ti layer 7b of FIG. 3J is etched away which releases the SU8 mask 8 from the membrane layers 2 and 3. This release is also referred to as a lift off process.

In step 113, plateable photoresist 10 of FIG. 3L is plated onto the seed layer of the membrane 7a and the nickel springs 9. This photoresist 10 is on both sides of the structure and after patterning leaves holes 10a, which will become the contact tips on both springs.

In step 114 as shown in FIG. 3M, a noble metal 11 resistant to wear such as Rhodium or PdCo is plated into the resist openings 10a of step 113. This creates spring tips which are structures 11.

In step 115, the plateable photoresist 10 is removed. Then, the Au/Cr seed layer 7a is etched followed by a Cu etch to remove the thick copper film 2. This will leave the nickel springs 9 isolated electrically and held together in the desired relative positions by the remaining polyimide film 3 as shown in FIG. 3N. The pattern in the polyimide 3 can be such that each group of springs would be held by an isolated area of polyimide forming a coupon. The perimeter of this coupon of polyimide will have a border of plated nickel 9a and 9b which serves to hold the polyimide in tension and consequently all the springs 9 in their original relative position. These isolated polyimide areas can have tabs of polyimide between each coupon such that they stay together in wafer shape and are held by the support ring of step 1. This makes the array of coupons easy to handle until each coupon is to be excised from the wafer. The final coupon can have multiple sets of springs similar to the arrangement shown in FIG. 1A.

In the above process flow of FIG. 2, a variation is possible to only use the SU8 thick resist on one side of the wafer. This can be done by adding a step after step 108 to pattern the seed layer of step 108 on the polyimide (top) side to take on the spring shapes. This can be done with a photoresist step following by an etch step. In this case, step 108 can also be modified to take out the Ti layer 7b since the release of the SU8 resist 8 will be accomplished by the final Cu etch to remove film 2. During Nickel plating of structure 9, the resist openings from step 109 will control the shapes of the springs on the bottom side where the patterned seed 7a on the top side will define the shape of the springs on the top side. Since the top side plating will grow both vertically as well as horizontally, the dimensions of the patterned seed will need to be compensated for the horizontal plating growth.

Table 1 below summaries process structures described in FIGS. 3A thru 3N.

TABLE 1
Process structure labels and target thicknesses for one embodiment

```
  1 Metal Support Ring
  2 Copper Foil (50 microns thick)
  3 Polyimide (15-20 microns thick)
  4 35 microns photoresist
  5 32 microns plated Cu
  6 Drilled via (50 to 75 microns)
  7a Cr (600 A) and Au (2000 A)
  7b Ti (2000 A)
  8 SU8 photoresist 60 microns
  9 Plated Ni 25 microns
  9a Ni stud for coupon attach
  9b Ni frame for coupon support
10 Plateable photoresist
11 Pd/Co tip
```

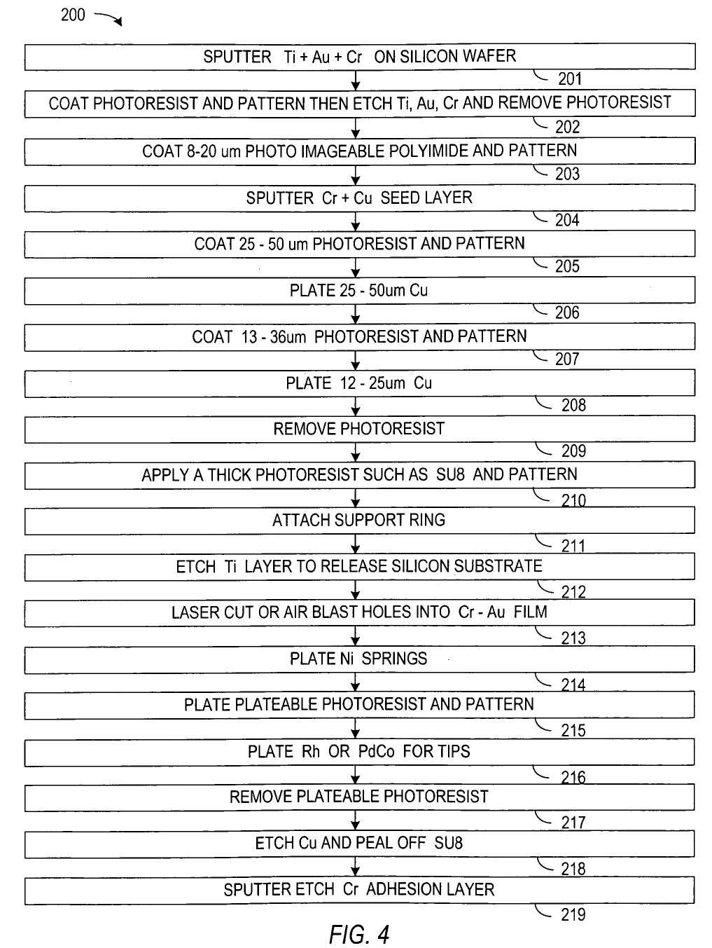

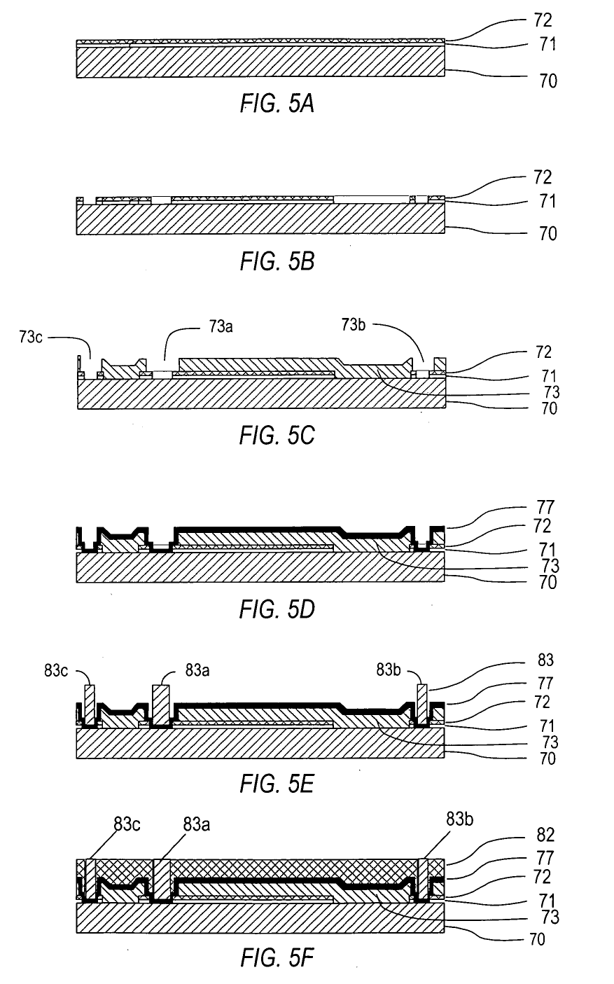

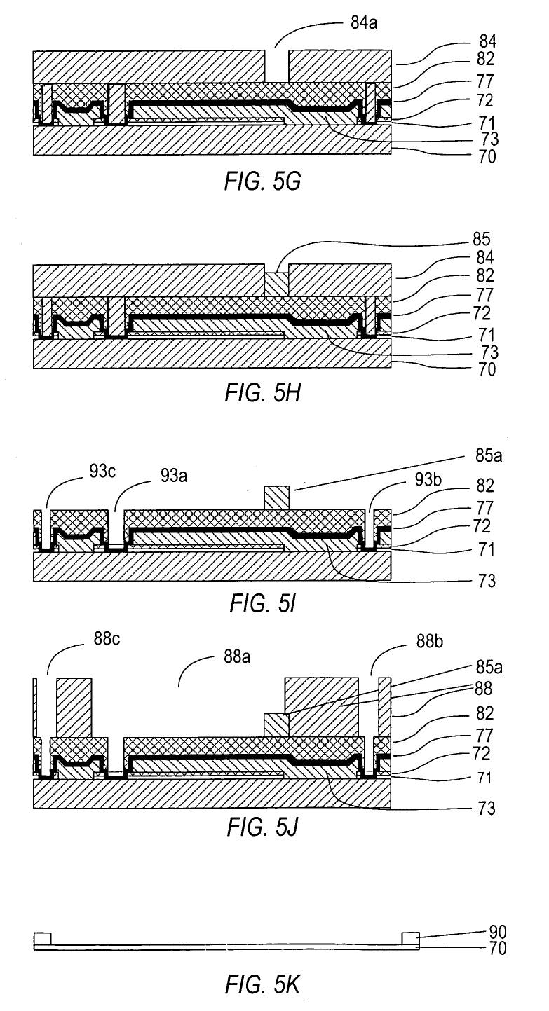

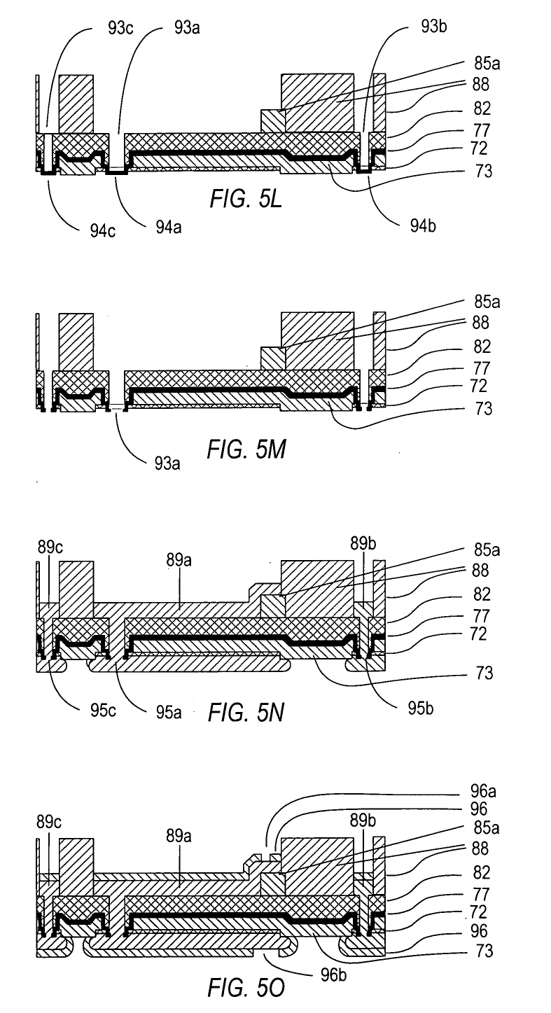

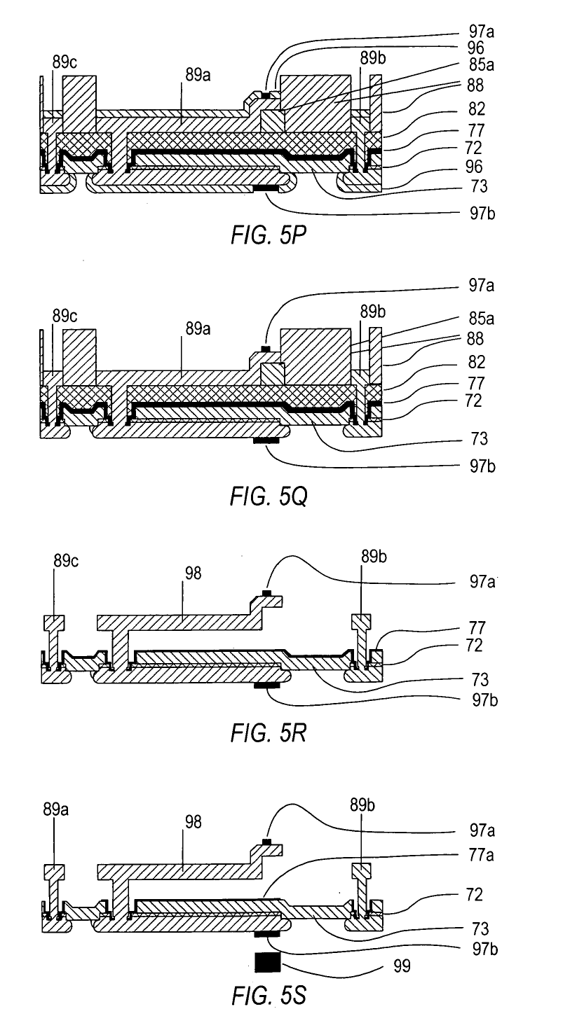

FIG. 4 shows a series of process steps that is another embodiment of a process flow used to fabricate springs on a membrane while in the shape of a wafer. The structures built using the process flow of FIG. 4 are shown in FIGS. 5A to 5S. FIG. 4 is an alternate process flow 200 to create a similar spring coupon structure as shown in FIG. 3N. The advantage of this flow is that most of the processing steps are performed on a solid substrate where the flow 100 of FIG. 2 requires processing on a film supported by a metal ring.

In step 201, a wafer 70 is coated with a Ti, Au layer 71 and then a Cr layer 72 as shown in FIG. 5A. The wafer 70 can be any conventional material such as silicon, ceramic, or glass. The Ti in layer 71 serves as a release layer as well as an adhesion layer and is preferably be 1000 A-5000 A thick. The Au in layer 71 serves as a conductive seed layer for later plating and is preferably 500 A-2000 A thick. The final Cr layer 72 serves as an adhesion layer for a follow polyimide processing step. The chrome layer 72 is preferably 100 A-500 A thick.

In step 202, a photoresist is spin coated and patterned on the wafer with the remaining resist depicting the shapes of the spring and other features to be later plated with nickel on the bottom side of the structure. The metal stack of Ti/Au/Cr in layers 71 and 72 is etched where there is no photoresist. The photoresist is then removed leaving the pattern in the metal stack shown in FIG. 5B. If additional adhesion is needed to the follow on polyimide step, then only the Au/Cr could be removed at this etch step.

In step 203, a photo-imageable polyimide 73 is coated on the wafer and patterned to provide via openings 73a where the base of the springs as well as other support structures will be formed and openings 73b and 73b where support structures will be formed. The polyimide 73 would preferably be 8-20 microns thick. The polyimide is then cured to harden the film. The resulting structure is shown in FIG. 5C.

In step 204, as shown in FIG. 5D, a Cr and Cu metal stack 77 is coated on top of the polyimide 73. The Cr in layer 77 could be 100 A-500 A and serves as an adhesion layer. The Cu in layer 77 would preferably be 500 A-2000 A and serves as a plating seed layer.

In step 205, a thick photoresist 83 is coated on the structure of FIG. 5D and patterned to form posts 83a, 83b, and 83c as shown in FIG. 5E. Posts 83a define future via openings in the following thick copper layer. This resist would preferably be 25-50 μm thick. The pattern defines posts 83a, 83b, and 83c in the photoresist 83 of 25 to 100 μm diameter in locations matching the vias 73a in the polyimide layer. The diameter of the posts will be a function of the spring design driven by the spring pitch. The edge of the wafer must be covered by this resist so that the polyimide will be exposed for mounting of a support ring 90 in step 211 as described below.

In step 206, copper 82 is plated to almost the height of the resist of step 205. This forms what will become a sacrificial layer that separates the top and the bottom springs as shown in FIG. 5F. The copper thickness is a function of the spring design and controls the maximum compliance of the springs. The base of each spring will have 1 or 2 vias 83a to anchor the bottom spring to the top spring.

In step 207, a thick photoresist 84 is coated on top of the plated copper 82 of step 206. Photoresist 84 is patterned as shown in FIG. 5G to define openings 84a in the resist where the tips of the top spring sections will be formed. The photoresist layer 84 would preferably be 13-36 microns thick.

In step 208, copper 85 of FIG. 5H is plated into the opening 84a defined by step 207 to create a post structure 85a shown in FIG. 5I. This post structure 85a will provide a raised tip for the top spring. The height of post 85a is designed to keep the top spring tip high enough so that when the spring is under compression, the base of the spring will not hit the IC wafer being tested.

In step 209, the photoresist 84 of step 207 as well as the photoresist 83 of step 205 are removed. The removal of resist 83 creates a vias 93a, 93b, and 93c as shown in FIG. 5I.

In step 210, a thick photoresist 88 such as SU8 is applied and patterned. This defines the openings for plating the top spring 88a and the support frame 88b as shown in FIG. 5J. The photoresist thickness needs to be high enough to cover the thickness of the plated spring plus the height of the post 85a of step 208. The edges of the wafer need to be cleared of photoresist 88 so that the polyimide 73 is exposed for mounting a support ring.

In step 211, a support ring 90 shown in FIG. 5K is attached to the peripheral of the wafer 70 on the polyimide surface 73. A suitable adhesive such as B-stage epoxy can be used for this attachment step. The will ring keeps the polyimide in tension to support the wafer shape when the wafer substrate 70 is removed. The supporting ring is not shown on the following figures, FIGS. 5L through 5S, since it is at the circumference of the wafer and very large relative to the spring dimensions being described and illustrated in FIGS. 5A to 5J.

In step 212, the Ti of layer 71 of step 201 is etched to release the substrate 70 of step 201. A portion of the released structure which is held in wafer form is shown in FIG. 5L. To aid etchant access to the Ti layer 71, a short copper etch can be added to remove the copper seed layer 77 which is on top of the Ti 71 in the vias 73a of step 203 (FIG. 5C). There is only a very thin seed layer of copper 77 when compared to the very thick copper layers 82, 85 everywhere else. The thickness of the thick copper will not be significantly reduced by this short etch.

In step 213, remaining chrome and copper shown as 94a in FIG. 5L at the bottom of the vias 93a, 93b, 93c is removed either by wet etch, laser ablation or air blast. This provides an opening in the resulting copper and polyimide film in each via as shown in FIG. 5M.

In step 214, stress free or slightly compressive nickel or nickel cobalt 89a, 89b, 89c is plated onto both sides of the wafer at the same time as shown in FIG. 5N. This will also plate the vias 93a connecting the top spring with the bottom spring. The size of the top spring will be defined by the trough created by the resist of step 210 whereas the bottom springs will be defined by the pattern of the Au—Cr layer patterned in step 202. The bottom springs will plate vertically as well as laterally. FIG. 5N shows the diameter of the polyimide via opening 95a, 95b, 95c bigger than the via openings 83a, 83b, 83c in the plated copper of step 206 (FIG. 5F). This arrangement is preferred to ensure electrical contact between the thick copper 82 of step 206 and the bottom seed layer 71, 72 of step 202 (FIG. 5B). Due to the lateral plating of the bottom seed metal pattern, this design will limit the minimum pitch of the springs by the diameter of the via 93a since the minimum width of the bottom seed pattern will have to be equal or larger than the diameter of via 93a. This can be circumvented by making the via opening in the polyimide layer smaller than via 95a. This is less optimal for the electrical contact and will require more stringent controls in the process the ensure yield.

In step 215, a plateable photoresist 96 is plated onto both sides of the structure as shown in FIG. 50. Both sides are exposed to define probe tip contact points 96a and 96b.

In step 216, the openings 96a and 96b defined by the plateable photoresist 96 are plated with a noble wear resistant metal such as rhodium and palladium cobalt creating probe tips 97a and 97b. This structure is shown in FIG. 5P.

In step 217, the plateable photoresist 96 is removed creating the structure shown in FIG. 5Q.

In step 218, all the copper is etched away. This includes the copper 85 plated in step 218, copper 82 of step 216 as well as the copper in seed layer sandwich 77 in step 214. This isolates all the plated nickel finger pairs thus creating a C shaped spring that is suspended by the polyimide film 73 as shown in FIG. 5R. Since the SU8 photoresist 88 is only held by the copper, it will also detach from the structure. Apart from the polyimide, the only material left connecting the plated fingers is the thin Cr layer of step 204 which was part of the Cr and Cu metal sandwich 77 and which is on the top surface of the polyimide 73.

In step 219, a sputter etch is used to remove the remaining Cr 77 and totally isolate the springs electrically. A wet etch can also be used here but the part must not be over etched causing the connection of the plated finger to the polyimide film to weaken. This resulting C-Spring shaped coupon structure shown in FIG. 5S is intended to be attached to a signal distribution HDI substrate which will have tall mating gold bumps 99 to make contact to the contact point of the lower spring 97b. The height of this bump 99 together with the raised tip of the top spring 97a ensures that the base of the spring 98 will not make contact with the device under test when the tip of the top spring is compressed. The final coupon consists of springs 98 which are attached to Polyimide structure 73 and stretched across frame 98a and 98b. The polyimide film 73 in the coupon keeps the probes and their tips of the top probes aligned to the pads of an IC being tested and the probes and tips of bottom probes aligned to the pads of a probe card high density interconnect that routes to an IC tester. This coupon structure is an alternative to the coupons of FIGS. 1A, 1B, and 1C.

Table 2 below summaries process structures described in FIGS. 5A thru 5S.

TABLE 2
Process structure labels and target thicknesses for one embodiment

| | |
|---|---|
| 70 | Staring Wafer |
| 71 | Ti: 1000-5000 A, Au: 500 A-2000 A |
| 72 | Cr: 100 A-500 A |
| 73 | Polyimide: 8-20 microns |
| 77 | Cr: 100-500 A, Cu: 500 A-2000 A |
| 82 | Plated Copper (25-50 microns thick) |
| 83 | Photoresist: 25-50 microns |
| 84 | Photoresist: 13-36 microns |
| 85 | Cu: 15-30 microns |
| 88 | 60 μm SU8 photoresist |
| 90 | Metal support ring |
| 93a, b, c | Vias |
| 95a, b, c | Vias |
| 96 | Plateable photoresist |
| 97a, b | Rh or PdCo probe tips |
| 98 | Spring base |
| 99 | Gold bumps on HDI |

Although the invention has been described with reference to particular embodiments, the description is only an example of the invention's application and should not be taken as a limitation. Various adaptations and combinations of features of the embodiments disclosed are within the scope of the invention.

What is claimed is:

1. A process for forming a spring network, comprising:
forming a membrane including a sacrificial material that is conductive;
attaching the membrane to a support ring;
depositing and patterning a non-conductive material on a first surface of the membrane;
plating the sacrificial material on the second surface of the membrane to create raised areas;
creating vias through the membrane;
plating patterns with a spring material on both sides of the membrane over the sacrificial material;
forming wear resistant tips on the spring material;
removing the sacrificial material; and
removing the membrane from the support ring.

2. The process of claim 1, wherein the membrane on the support ring is in a shape of a round wafer.

3. The process of claim 1, wherein removing the membrane from the support ring creates a plurality of individual coupons with each of the coupons comprising a set of springs for contacting a device under test.

4. The process of claim 1, wherein the spring material is selected from a group consisting of nickel and nickel cobalt.

5. The process of claim 1, wherein the sacrificial material is copper.

6. The process of claim 1, wherein the wear resistant tip comprises a material selected from a group consisting of rhodium and palladium cobalt.

7. The process of claim 1, wherein forming the membrane comprises depositing the sacrificial material over a release layer on a hard substrate and subsequently releasing the substrate after depositing and patterning the non-conductive material and attaching the supporting ring.

8. A process for forming a spring network, comprising:
depositing a release layer on a sacrificial substrate;
depositing and patterning a non-conductive material on the release layer;
depositing a conductive sacrificial material over the non-conductive material;
plating sacrificial material in a pattern on the conductive material to create raised areas;
attaching a support ring to the patterned side of the substrate;
releasing the substrate from the membrane;
creating vias through the membrane;
plating patterns of a spring material on both sides of the membrane;
forming wear resistant tips on the spring material;
removing the sacrificial material; and
removing the membrane from the support ring.

9. The process of claim 8, wherein the membrane on the support ring is in a shape of a round wafer.

10. The process of claim 8, wherein removing the membrane from the support ring creates a plurality of individual coupons with each of the coupons comprising a set of springs for contacting a device under test.

11. The process of claim 8, wherein the spring material is selected from a group consisting of nickel and nickel cobalt.

12. The process of claim 8, wherein the sacrificial material is copper.

13. The process of claim 8, wherein the wear resistant tip comprises a material selected from a group consisting of rhodium and palladium cobalt.

14. A process for forming a spring network, comprising:
depositing and patterning a sandwich layer comprising a release material and a conductive material on a sacrificial substrate;
depositing and patterning a insulating material layer over the sandwich layer;
depositing a conductive material on the insulating material;
patterning shapes on the conductive material;
plating sacrificial material on the shapes to create raised area;
attaching a supporting ring;
releasing the sacrificial substrate to form a membrane supported by the support ring;
creating vias through the membrane;
plating a spring material in patterns on both surfaces of the membrane over the sacrificial material and filling the vias with the spring material;
forming a wear resistant tips on the spring material;
removing the sacrificial material; and
removing the membrane from the ring.

15. The process of claim 14, wherein removing the membrane from the ring produes a plurality of individual coupons with each of the coupons comprising a set of springs for contacting a device under test.

16. The process of claim 14, wherein the spring material is selected from a group consisting of nickel and nickel cobalt.

17. The process of claim 14, wherein the sacrificial material is copper.

18. The process of claim 14, wherein the tip material is selected from a group consisting of rhodium and palladium cobalt.
